(19) United States
(12) Patent Application Publication
(10) Pub. No.: US 2011/0197525 A1
(43) Pub. Date: Aug. 18, 2011

(54) TRIM FOR A BUILDING FRONTAGE

(75) Inventors: Xavier Balduini, Belfort (FR); Jean Maillard, Mulhouse (FR)

(73) Assignee: OPALY, Belfort (FR)

(21) Appl. No.: 13/125,707

(22) PCT Filed: Oct. 23, 2009
(86) PCT No.: PCT/FR2009/052037

§ 371 Date: Apr. 22, 2011

(30) Foreign Application Priority Data
Oct. 29, 2008 (FR) 0857379

(51) Int. Cl. F24J 2/52; H01L 31/18; F24J 2/00

(52) U.S. Cl. 52/173.3; 29/890.033; 29/897.3

(57) ABSTRACT

The invention relates to a method for trimming a building frontage. The method includes: applying an insulation onto said wall, from the wall towards the outside; applying a solar receptor after the insulation; forming a channel between the insulation and a rigid outer layer; placing a partially transparent and/or cut-out flexible strip therein; closing the channel with the outer layer having at least 90% of the surface thereof made of at least one transparent or translucent protection feature. The invention also relates to a kit for trimming a building frontage capable of being implemented by the method.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

1. Field of the Invention

The invention relates to a method for trimming a building frontage, including a wall.

The invention also relates to a kit for trimming a frontage, designed capable of being placed onto a wall or an insulation said frontage includes, and including, from said frontage to an external environment:
at least one solar receptor; and
a channel separating said solar receptor from a rigid external layer, which is in the vicinity of said external environment.

The invention is related to the field of trimming of building frontages in order to provide them with particular functions, essentially an energy-exchange function, and, in particular, the recovery of energy available in an environment external to the building, namely solar energy.

2. Description of Related Art Including Information Disclosed Under 37 CFR 1.97 and 37 CFR 1.98.

Though the design of new buildings integrates the notion of energy recovery, this is not the case for old buildings for which nothing was thought of to this end. It is known to adapt, especially on the roof, solar panels or photovoltaic panels as in FR 2 876 840. Such adaptations are either voluminous and heavy, in the case of the solar panels, or of a high purchase cost, in the case of the photovoltaic panels, and are also not aesthetical. Also known is to equip frontages with water circulation heated by solar radiation, in the case of FR 2 579 303. Such installations for solar radiation exchange with a liquid fluid are long and expensive to implement.

### SUMMARY OF THE INVENTION

The invention is aimed at coping with the problem of the state of the art by providing a method and means for trimming a frontage, which are very easy to be implemented by staff without any particular qualification, and using a large number of components easily available on the market at any place.

To this end, the invention relates to a method for trimming a building frontage including a wall,

wherein, from said wall outwardly, the level of insulation of said wall is measured and an eventual complementary layer of insulation is determined, depending on the specifications;

wherein, should the case arise, at least one said complementary layer of insulation is arranged onto said wall;

wherein at least one solar receptor is arranged on said wall or on said complementary layer of insulation farthest away from said wall;

wherein, beyond said most external solar receptor is formed, there is at least one channel between said solar receptor and a rigid external layer;

wherein, in at least one such channel, there is arranged at least one partially transparent or/and cut-out or/and perforated internal flexible strip;

wherein said internal flexible strip is arranged over the full height of a module forming an element of the building frontage, or over the full height of said building, hooked on an upper bearing surface and tensioned by tensioning means; and

wherein each channel is closed by said rigid external strip including at least either transparent or translucent protection means over at least 90% of their surface, or at least one external strip having a light-transmission coefficient higher than 25%, made in the form of a textile or a grid maintained tensioned within a frame.

The invention also relates to a trimming kit for a frontage, designed capable of being applied onto a wall or onto an insulation said frontage includes, and including, from said wall to an external environment:
at least one solar receptor; and
a channel separating said solar receptor from a rigid external layer, which is in the vicinity of said external environment,

wherein said channel contains, between said solar receptor and said rigid external layer, at least one internal flexible strip, which is partially transparent or/and cut-out or/and perforated, and said rigid external layer includes at least either one transparent or/and cut-out or/and perforated external strip having a light-transmission coefficient higher than 25%, or transparent or translucent protection means over at least 90% of their surface.

Further features and advantages of the invention will become clear from the following detailed description of non-restrictive embodiments of the invention, with reference to the attached figures.

### BRIEF DESCRIPTION OF THE DRAWINGS

FIG. 1 represents schematically, partially and in cross-section, a trimming for a frontage according to the invention.

FIG. 2 is a schematic view similar to FIG. 1, over the full height of a frontage.

FIG. 3 is a schematic and cross-sectional view of a particular way of assembling the protection means the invention includes.

FIG. 4 is a schematic and perspective view of a particular way of assembling the protection means the invention includes.

FIG. 5 represents schematically, partially and in cross-section, a trimming for a frontage according to a variant of the invention implementing sandwich panels.

FIG. 6 is a schematic view similar to FIG. 5, with variants for applying protection means the invention includes.

FIG. 7 represents schematically and in cross-section, a variant embodiment of the invention.

FIG. 8 and FIG. 9 are schematic views, representing, in similar ways, two different states of one and the same variant.

FIGS. 10 and 11 are schematic views, representing, in similar ways to FIG. 8, two different states of a perforated internal flexible strip the invention includes.

FIG. 12 represents schematically and in cross-section, a cheap variant embodiment of the invention.

### DETAILED DESCRIPTION OF THE DRAWINGS

The invention is related to the field of trimming for building frontages. This trimming is designed so as to permit to recover the energy available in the environment E external to the building, namely the solar energy, through exchange and concentration on a receptor. It is also designed to add value to the building by using particular materials, and to serve as a communication medium, and namely an advertisement medium. The invention uses components available on the market, permits a very easy placing by staff without any particular qualification, and does not require removing the frontage protection elements already installed, in particular the paneling panels the frontages of the industrial buildings are usually trimmed with.

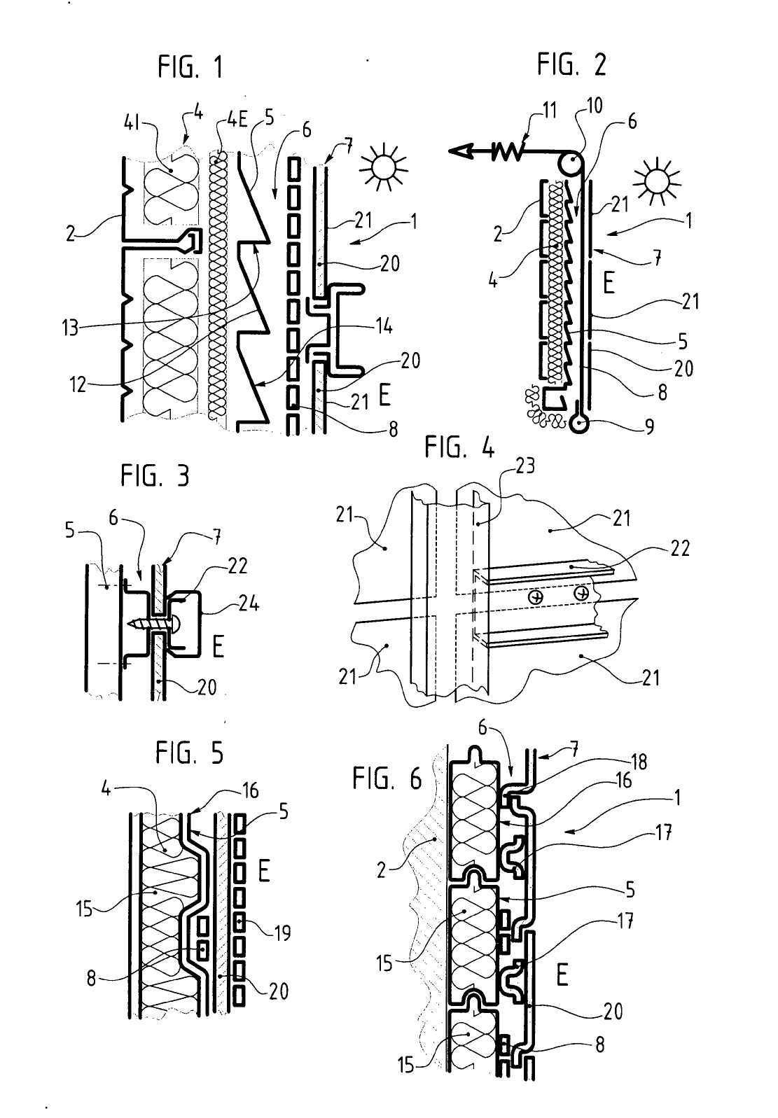

The invention implements a method for trimming, according to customer specifications, a building frontage, or a frontage portion, including a wall 2 oriented towards the exterior E. According to this method, from this wall 2 towards the exterior E:
the level of insulation of the wall 2 is measured and an eventual complementary layer of insulation 4 is determined, depending on the specifications;
should the case arise, at least one such complementary layer of insulation 4 is arranged on the wall 2, when the preceding calculation has shown its need. It is obvious that, as shown in FIG. 1, several layers, from an internal layer 41 proximate the wall 2, which is for example formed of a traditional industrial paneling, to an external layer 4E farthest away from the wall 2;
at least one solar receptor 5 is arranged on the wall 2 or, if necessary, on the complementary layer of insulation 4 farthest away from the wall 2;
beyond this most external solar receptor 5 is formed, in the event various solar receptors are arranged stepwise at different distances from the wall 2, at least one channel 6 between this solar receptor 5 and a rigid external layer 7;
in at least one such channel 6 is arranged at least one partially transparent or/and cut-out or/and perforated internal flexible strip 8. In a preferred embodiment, this internal flexible strip 8 is formed of a film or a textile designed capable of carrying a decoration, which film is cut-out or perforated. This internal flexible strip 8 is arranged over the full height of a module forming a frontage element of the building, or over the full height of the building, hooked on an upper bearing surface 10 and tensioned by tensioning means 11;
each channel is closed by the rigid external layer 7.

According to the invention, this rigid external layer 7 includes at least either transparent or translucent protection means 20 over at least 90% of their surface, or at least one external strip 19 having a light-transmission coefficient higher than 25%, made in the form of a textile or a grid maintained tensioned within a frame.

Of course, the rigid external layer 7 can include both such protection means 20 and one or several such external strips 19.

In a preferred embodiment, the rigid external layer 7 formed over at least 90% of its surface by at least one transparent or translucent protection means 20, such as a glass panel, a diffusing panel, or the like is chosen. Preferably, this rigid external layer 7 is air-tight and weather-tight.

It is obvious that the internal flexible strip 8 permits partial entering of the solar radiation into the channel 6 and it is preferably designed capable of impeding the transmitted energy from leaving to the external environment. For example, the internal flexible strip 8 can be metallized or include a reflecting coating on its internal face opposite the external environment E. The internal flexible strip 8 can also be formed by perforated sheet metal, a grid or the like.

In a preferred embodiment, as visible in FIG. 2, the internal flexible strip 8 is arranged over the full height of a portion of the frontage, which can namely be made of at least one module the frontage of the building includes, for example according to the application FR 08 52129 of the same applicant, or over the full height of the building.

This internal flexible strip 8 is, in a first embodiment, hooked on an upper bearing surface 10 and tensioned by tensioning means 11 such as a weighted shaft or the like.

In a second embodiment, said internal flexible strip 8 is arranged between a lower bearing surface 9 and an upper bearing surface 10, at least one of the lower 9 and upper 10 bearing surfaces including means for tensioning 11 the internal flexible strip 8, such as an eccentric, spring, tensioner or the like. Advantageously, the tensioning means 11 are made according to the application FR 08 52144 of the same applicant.

In an advantageous variant embodiment, the protection means 20 is formed by a juxtaposition of transparent or translucent panels 21 assembled by horizontal rails 22 or/and vertical stiles 23, as visible in FIG. 4. These horizontal rails 22 and these stiles 23 can form mullions protruding with respect to the external surface of the protection means 20, or be flush with the level of this surface. In an advantageous embodiment, as visible in FIGS. 3 and 4, the horizontal rails 22, which are capable of supporting the weight of the panels 21, are inserted against the receptor 5, which is slightly distant from same. These rails 22 can include a U-shaped profile, for example made of 1 mm thick galvanized sheet metal, which can be covered by a U-shaped cover 24, for example made of 0.75 mm thick pre-lacquered galvanized sheet metal, mounted upside down on that of the rails 22. The stiles 23 are advantageously U-shaped profiles available on the market, mounted in the same directions as the covers 24.

In a particularly cheap embodiment permitting to use non-finished products available on the market, a solar receptor 5 is chosen, which is formed of sheet metal with a zigzag profile with alternately, on the one hand, faces arranged horizontally 13 and, on the other hand, faces arranged obliquely 14 and parallel to each other, the normal line of which protruding to the exterior E is ascending. A standard <<Hacierba 5.200.50 HB>> type product is well-suited for such a use.

From the same viewpoint of saving and easy implementation with products available on the market, at least one sandwich panel 15, the most external face of which forms the solar receptor 5, as visible in FIGS. 5 and 6, is advantageously chosen for the complementary insulating layer 4.

In this embodiment, the protection means 20 is preferably fixed to the sandwich panel 15, at the level of the outermost face 16 of the latter, directly or through supporting spacers 17, so as to form at least one channel 6 between the sandwich panel 15 and the protection means 20. The use of sandwich panels including set-backs, as shown in FIG. 5, permits to create as many channels 6 parallel to each other.

In an advantageous embodiment of the invention, the protection means 20 is chosen made out of transparent polycarbonate and is folded at least at one of its ends, in order to form the supporting spacer 18, as visible in FIG. 6. This figure shows both this direct way of resting of the protection means 20 on a sandwich panel 15 and the indirect way of resting through spacers 17. It is obvious that either way of fixing can be chosen, or that they can be cumulated according to the example of FIG. 6. A 4 mm thickness of the panels 21 is enough to ensure a proper parallelism between them. The horizontal rails 22 ensure the rigidity of the whole, wherefore it is not necessary to use panels with a larger thickness, which contributes to the low cost price of the whole.

In a preferred embodiment, when the protection means 20 consists of a juxtaposition of transparent panels 21 assembled by horizontal rails 22 or/and vertical stiles 23, the internal flexible strip 8 is tensioned between horizontal rails 22.

The partially transparent or/and cut-out or/and perforated internal flexible strip 8 is preferably made removable, and is then fixed with reversible fixing means designed capable of permitting its quick exchange, made of Velcro, or by press-buttons, or by snap-on fasteners with lever effect or clamping, or by clips, or by magnets, or by screwing means, or the like. The internal flexible strip 8 can then act as communication means, and this function is conjugated with its primary solar radiation catching function.

In a variant embodiment, as visible in FIG. 5, an external strip 19 is juxtaposed to the protection means 20, which is also chosen partially transparent or/and cut-out or/and perforated, and preferably removable, in order to permit an effect complementary to the internal strip 8.

The partially transparent or/and cut-out or/and perforated internal flexible strip 8 is, in a particular embodiment, applied directly onto transparent or translucent protection means 20, by gluing, or by electrostatic assembling or by magnetization or by welding, or the like.

The invention also relates to a kit for trimming a frontage on a wall 2 this frontage includes.

The trimming of a wall or a frontage by means of such a trimming kit 1 can occur according to the above-described method.

The kit for trimming a frontage, designed capable of being applied against a wall 2 or against an insulation this frontage includes, comprises, from the frontage towards the external environment E:
at least one solar receptor 5; and
a channel 6 separating this solar receptor 5 from a rigid external layer 7, which is in the vicinity of said external environment E.

According to the invention, this channel 6 contains, between this solar receptor 5 and the rigid external layer 7, at least one internal flexible strip 8, which is partially transparent or/and cut-out or/and perforated.

The kit can also include, in the channel 6, further internal strips 8.

The rigid external layer 7 includes at least either at least one external strip 19 having a light-transmission coefficient higher than 25% and which is partially transparent or/and cut-out or/and perforated, or transparent or translucent protection means 20 over at least 90% of the surface of this external layer 7.

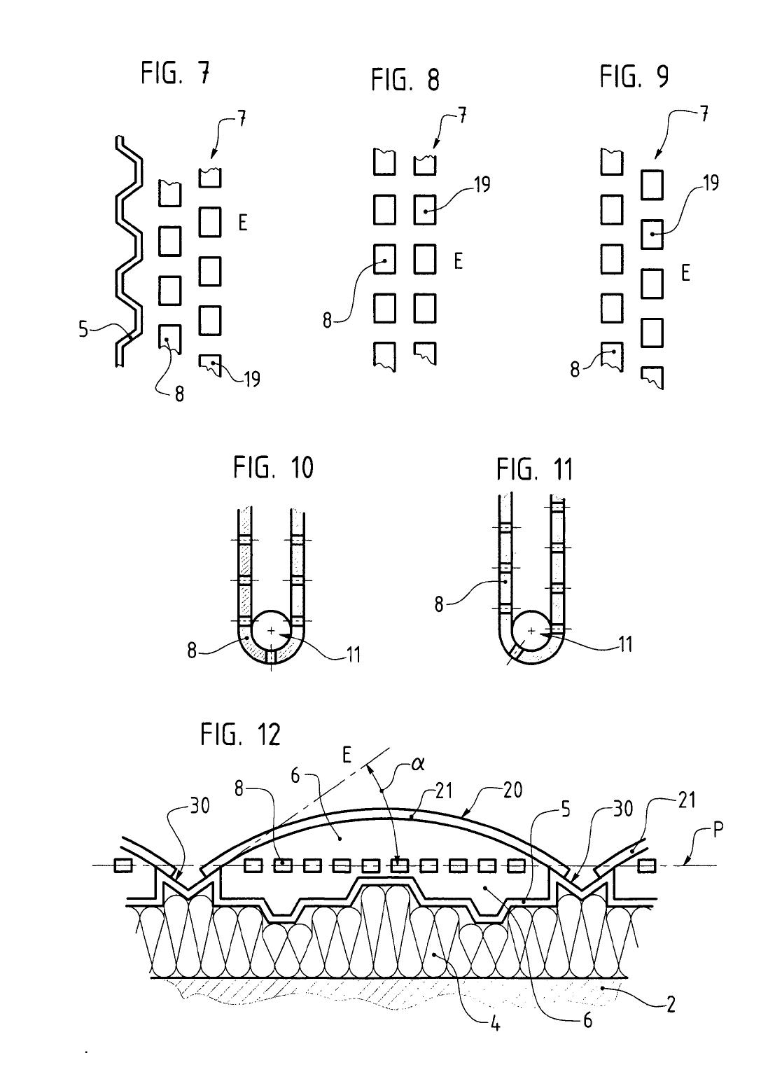

On the side of the external environment E, the rigid external layer 7 can include:
at least one external strip 19, as visible in FIG. 5 or 7; and/or
protection means 20, as visible in FIGS. 1, 2 and 6, where they are arranged as close as possible to the external environment E.

The latter protection means 20 advantageously include at least one transparent panel 21.

When the kit includes both at least one external strip 19 and at least protection means 20, the latter can be arranged either as close as possible to the external environment E, or between the channel 6 and the external strip 19, which is then arranged as close as possible to the external environment E, as visible in FIG. 5.

Advantageously, the internal flexible strip 8 is arranged over the full height of a module forming an element of the frontage of the building, or over the full height of the building, hooked on an upper bearing surface 10, and tensioned by tensioning means 11. More particularly, the internal flexible strip 8 is arranged between a lower bearing surface 9 and an upper bearing surface 10, at least one of the lower 9 and upper 10 bearing surfaces including means for tensioning 11 the internal flexible strip 8.

In a particular embodiment, the kit for trimming a building frontage 1 includes, on the transparent or translucent protection means 20 and on the side of the external environment E, a partially transparent or/and cut-out or/and perforated external strip 19.

In an advantageous variant embodiment, the solar receptor 5 is made out of sheet metal or the like, and incorporates bosses for supporting the external layer 7, namely protection means 20 making the use of spacers useless. In a preferred embodiment, as visible in FIG. 12, these bosses include surfaces 30 sloping with respect to a general plane P according to which the solar receptor 5 develops, which sloping surfaces 30 are designed so as to receive the edges of transparent panels 21, namely made of polycarbonate, or also the edges of frames for maintaining external strips 19, so as to fix the latter with a slight curve, nearly invisible to the naked eye, which has the advantage of absorbing the dilatations of the material. The angle of gradient a between each sloping surface and the plane P is smaller than 10°, and preferably smaller than 5°.

Preferably, in these various embodiments, when different webs interposed on the path of the solar radiation, formed, as the case may be, by one or several strips 8, one or several external strips 19, one or several protection means 20 or transparent panels 21, are juxtaposed substantially parallel to each other, it is important that the degree of opening of those webs that are perforated or cut-out are in an order with respect to each other, so as to ensure the best possible thermal yielding. To this end, it is preferred that the degree of opening of the web farthest away from the external environment E is smaller than that of the web closest to this external environment E.

Preferably, the degree of opening, i.e. the ratio between the perforated or cut-out surface and the total surface, is preferably smaller than 0.50 for an internal flexible strip 8, namely when it is made in the form of a textile.

It is also advantageous to change the degree of opening of one or several webs depending on the level of elevation with respect to the ground, so as to ensure a uniform distribution over the height of the building. As visible in FIGS. 8 and 9, it is possible to act, in a micrometrical way, on the relative position in height of a web with respect to another one, so as to permit, or to restrict, to a maximum extent, the passing through of the solar radiation. This micrometrical adjustment then permits to take into consideration the azimuth of the sun with respect to the building, depending on the moment of the day or/and the season, in order to change the relative alignment of the openings of the webs depending on the inclination of the solar radiation with respect to the normal line to the frontage. Likewise, as visible in FIGS. 10 and 11, it is possible to use a double web, for example an internal flexible textile strip 8, weighted by means of a ballast, such as a shaft, a bar or the like forming tensioning means 11, strip 8 a partial winding-up of which permits to align the openings, or to hide them.

In the event the webs used, in particular the internal strip 8 or also the external strip 19, are of a large length, any crimps likely to close the air path and to create pressure drops should be avoided. To this end, it is possible to laterally guide this web by means of guides in a substantially vertical direction, or, in simpler and cheaper way, by stiffening this web or strip with stiffeners that are either applied like horizontal busks or formed by a welded or glued horizontal fold, or the like. When the web or strip unfolds away from a structure including mullions, as in the examples of FIG. 3 or 4, the distance between stiffeners is advantageously identical to that between the horizontal mullions, which permits to hide the stiffeners behind the latter.

The trimming kit can also include an additional insulation 4 on the side of its placing on the frontage.

Like the frontage trimming 1, the trimming kit can be made very easy to be placed through the incorporation of one or several frames, preferably removable frames, namely for holding an internal strip 8, or also for holding an external strip 19. This frame is preferably independent from the solar receptor 5, as well as from the protection means 20. This independency permits to have a removable frame very light to be handled, and permits to very easy change the solar filtration and, of course, to change the esthetics of a so equipped frontage.

In brief, irrespective of the embodiment of the invention, the channel 6 always includes, between the solar receptor 5 and the external environment E, an internal flexible strip 8. The latter is continuous and formed, as the case may be, of an cut-out flexible film of polycarbonate or the like, or also of a textile. The degree of opening of this internal flexible strip is preferably between 10 and 50%.

The channel 6 is closed, on the side of the external environment E, by a rigid external layer 7, which is formed either by protection means 20 including at least a transparent panel 21, which is transparent or translucent over at least 90% of its surface or by an external strip 19, advantageously made in the form of a textile or a grid maintained tensioned in a frame, and having a light-transmission coefficient higher than 25%.

The various most usual alternatives relating to the constitution of this rigid external layer 7 and the arrangement and the placing of the kit, from the wall 2 towards the external environment E are:
solar receptor 5, flexible strip 8, protection means 20;
solar receptor 5, flexible strip 8, protection means 20, external strip 19;
solar receptor 5, flexible strip 8, external strip 19; and
solar receptor 5, flexible strip 8, rigid external strip 19, protection means 20.

1. Method for trimming a building frontage including wherein the frontage is comprised of a wall, and wherein the method starts from said wall towards an exterior, said method comprising the steps of:
measuring a the level of insulation of said wall and determining an eventual complementary layer of insulation;
arranging, if necessary, at least one said complementary layer of insulation on said wall;
arranging at least one solar receptor on said wall or on said complementary layer of insulation farthest away from said wall;
forming, beyond a most external solar receptor, at least one channel between said solar receptor and a rigid external layer;
arranging, in at least one such channel, at least one partially transparent or/and cut-out or/and perforated internal flexible strip;
arranging said internal flexible strip over a full height of a module forming a frontage element of the building, or over the full height of the building, hooked on an upper bearing surface and tensioned by tensioning means; and
closing each channel by said rigid external layer, being comprised of at least either transparent or translucent protection means over at least 90% of a surface, or at least one external strip having a light-transmission coefficient higher than 25%, made in the form of a textile or a grid maintained tensioned within a frame.

2. Method according to claim 1, wherein said internal flexible strip is arranged between a lower bearing surface and an upper bearing surface, at least one of the lower and upper bearing surfaces comprising means for tensioning said internal flexible strip.

3. Method according to claim 1, wherein said solar receptor comprises sheet metal with a zigzag profile with alternately faces arranged horizontally and, faces arranged obliquely and parallel to each other, a normal line of faces protruding to the exterior is ascending.

4. Method according to claim 1, wherein insulation of said complementary layer is comprised of at least one sandwich panel having a most external face forming said solar receptor.

5. Method according to claim 4, wherein said protection means is fixed to said sandwich panel, directly or through supporting spacers so as to form at least one channel between said sandwich panel and said protection means.

6. Method according to claim 1, wherein said internal flexible strip is removable and fixed with reversible fixing means permitting its quick exchange, being comprised of Velcro(™), or by press-buttons, or by snap-on fasteners with lever effect or clamping, or by clips, or by magnets, or by screwing means.

7. Method according to claim 1, wherein said rigid external layer comprises transparent or translucent protection means over at least 90% of their surface, and wherein said internal flexible strip is applied directly on said transparent or translucent protection means, by gluing, or by electrostatic assembling or by magnetization or by welding.

8. Kit for trimming a frontage, being applied onto a wall or onto an insulation of said frontage, said kit comprising:
at least one solar receptor; and
a channel separating said solar receptor from a rigid external layer, wherein the solar receptor and said channel are positioned from said wall to an external environment, the rigid external layer being in a vicinity of said external environment,
wherein said channel contains comprises, between said solar receptor and said rigid external layer, at least one internal flexible strip being partially transparent or/and cut-out or/and perforated, and wherein said rigid external layer comprises at least either at least one transparent or/and cut-out or/and perforated external strip having a light-transmission coefficient higher than 25%, or transparent or translucent protection means over at least 90% of their surface.

9. Kit for trimming a frontage according to claim 8, wherein said rigid external layer comprises transparent or translucent protection means over at least 90% of its surface, and wherein said protection means are arranged as close as possible to the external environment.

10. Kit for trimming a frontage according to claim 8, wherein said rigid external layer comprises one said partially transparent or/and cut-out or/and perforated external strip having a light-transmission coefficient higher than 25% and transparent or translucent protection means over at least 90% of a surface of the strip, and wherein said protection means are arranged between said channel and said external strip, being arranged as close as possible to said external environment.

11. Kit for trimming a frontage according to claim 8, wherein said rigid external layer comprises one said partially transparent or/and cut-out or/and perforated external strip having a light-transmission coefficient higher than 25%, being arranged as close as possible to the external environment.

12. Kit for trimming a frontage according to claim 8, further comprising:
at least one removable frame, for holding an internal flexible strip, or/and an external strip.

13. Kit for trimming a frontage according to claim 8, wherein said internal flexible strip is removable and arranged over the full height of said kit or a module of said kit, said internal flexible strip being hooked on an upper bearing surface, and tensioned by tensioning means.

14. Kit for trimming a frontage according to claim 8, wherein said solar receptor comprises bosses for supporting said rigid external layer, said bosses having sloping surfaces with respect to a general plane according to said solar receptor, the surfaces receiving the edges of transparent panels or frames for holding external strips so as to fix said edges with a slight curve in order to absorb the dilatations of the material, according to an angle of gradient (α) between said sloping surface and said plane, which is smaller than 10°.

15. Kit for trimming a frontage according to claim 8, further comprising:
at least one complementary insulation layer fixed to said wall, and to which wherein at least one said solar receptor is fixed the complementary insulation layer.
